(19) United States
(12) Patent Application Publication
(10) Pub. No.: US 2026/0016910 A1
(43) Pub. Date: Jan. 15, 2026

(54) TOUCH-CONTROL DISPLAY PANEL AND MANUFACTURING METHOD THEREFOR, AND DISPLAY DEVICE

(71) Applicants: Chengdu BOE Optoelectronics Technology Co., Ltd., Sichuan Province (CN); BOE Technology Group Co., Ltd., Beijing (CN)

(72) Inventors: Lihui LUO, Beijing (CN); Peng HOU, Beijing (CN); Youchun CHEN, Beijing (CN); Jianbo XIAN, Beijing (CN)

(21) Appl. No.: 18/994,427

(22) PCT Filed: Apr. 16, 2024
(86) PCT No.: PCT/CN2024/088109

§ 371 Date: Jan. 14, 2025

(30) Foreign Application Priority Data
May 26, 2023 (CN) 202310602917.8

(51) Int. Cl. G06F 3/041; H10K 59/12; H10K 59/131; H10K 59/38; H10K 59/40; H10K 59/80; H10K 102/00

(52) U.S. Cl. CPC G06F 3/0412; H10K 59/1201; H10K 59/131; H10K 59/38; H10K 59/40; H10K 59/873; H10K 59/8792; G06F 2203/04103; H10K 2102/351

(57) ABSTRACT

A touch-control display panel and a manufacturing method, and a display device. The touch-control display panel includes a display structure layer, an encapsulating layer and an optical adjusting structure which are sequentially arranged on a substrate. The touch-control display panel further includes: a metal lapping hole disposed on the substrate and located in the bonding region; two protective layers on one side of the optical adjusting structure away from the substrate; and a touch-control structure layer on one side of the two protective layers away from the substrate. The touch-control structure layer includes a touch-control electrode lead, and a part of the touch-control electrode lead covers the metal lapping hole.

### CROSS-REFERENCE TO RELATED APPLICATION

This application is a National Stage of International Application No. PCT/CN2024/088109, filed on Apr. 16, 2024, which claims priority to Chinese Patent Application No. 202310602917.8, filed with the China National Intellectual Property Administration on May 26, 2023, and entitled “Touch-Control Display Panel and Manufacturing Method therefor, and Display Device”, the content of which is hereby incorporated by reference in its entirety.

### TECHNICAL FIELD

The present disclosure herein relates to the technical field of touch-control display, and in particular to a touch-control display panel and a manufacturing method therefor, and a display device.

### BACKGROUND

With the continuous development of electronic products, Organic Light Emitting Diode (OLED) display devices can realize full screen, narrow frame, high resolution, curled wearing, folding, etc., and have been widely used.

### SUMMARY

Embodiments of the present disclosure provide a touch-control display panel and a manufacturing method therefor, and a display device, and specific solutions are as follows.

Embodiments of the present disclosure provide a touch-control display panel, including a display region and a peripheral region surrounding the display region; where the peripheral region includes a first frame region at one side of the display region, the first frame region includes a bonding region and a transition region between the bonding region and the display region; the touch-control display panel includes:
a substrate;
a display structure layer, arranged on the substrate and located in the display region;
an encapsulating layer, on one side of the display structure layer away from the substrate, where at least a part of the encapsulating layer is located in the display region;
an optical adjusting structure, on one side of the encapsulating layer away from the substrate;
a metal lapping hole, disposed on the substrate and located in the bonding region;
at least two protective layers, on one side of the optical adjusting structure away from the substrate, where orthographic projections of the at least two protective layers on the substrate cover the display region and at least cover a part of the first frame region, the orthographic projections of the at least two protective layers on the substrate and an orthographic projection of the metal lapping hole on the substrate do not overlap, and a distance between boundaries of the orthographic projections of the at least two protective layers in the first frame region is greater than or equal to a preset distance; and
a touch-control structure layer, on one side of the at least two protective layers away from the substrate, where the touch-control structure layer includes a touch-control electrode lead, and at least a part of the touch-control electrode lead covers the metal lapping hole.

Optionally, in the touch-control display panel according to embodiments of the present disclosure, the touch-control display panel further includes a first blocking dam and a second blocking dam in the transition region and spaced apart, where the first blocking dam surrounds a periphery of the display region, the second blocking dam surrounds a periphery of the first blocking dam;
where the at least two protective layers include a first protective layer, a boundary of an orthographic projection of the first protective layer on the substrate includes a first boundary in the first frame region, and the first boundary is on one side of the second blocking dam away from the first blocking dam.

Optionally, in the touch-control display panel according to embodiments of the present disclosure, the bonding region includes a first metal lapping electrode on the substrate, the first frame region includes a first planarization structure on one side of the first metal lapping electrode away from the substrate, an orthographic projection of the first planarization structure on the substrate covers the bonding region and a part of the transition region, and the first planarization structure and the second blocking dam are spaced apart, the first planarization structure includes the metal lapping hole, and an orthographic projection of the metal lapping hole on the substrate is within a range of an orthographic projection of the first metal lapping electrode on the substrate;
the first boundary is at least within an edge of the orthographic projection of the first planarization structure on the substrate.

Optionally, in the touch-control display panel according to embodiments of the present disclosure, the at least two protective layers further include a second protective layer; a boundary of an orthographic projection of the second protective layer on the substrate includes a second boundary in the first frame region, the second boundary is on one side of the second blocking dam close to the display region, or, the second boundary is on one side of the first blocking dam close to the display region.

Optionally, in the touch-control display panel according to embodiments of the present disclosure, the first boundary is at least close to the metal lapping hole.

Optionally, in the touch-control display panel according to embodiments of the present disclosure, the first boundary is on one side of the metal lapping hole away from the display region, and the first protective layer includes a first via hole, an orthographic projection of the first via hole on the substrate covers the orthographic projection of the metal lapping hole on the substrate.

Optionally, in the touch-control display panel according to embodiments of the present disclosure, the at least two protective layers further include a second protective layer; a boundary of an orthographic projection of the second protective layer on the substrate includes a second boundary in the first frame region, the second boundary is between the first planarization structure and the display region.

Optionally, in the touch-control display panel according to embodiments of the present disclosure, a thickness of the first protective layer in a region of the metal lapping hole is less than 3 μm.

Optionally, in the touch-control display panel according to embodiments of the present disclosure, the first protective layer is between the optical adjusting structure and the touch-control structure layer, and a second protective layer is between the first protective layer and the optical adjusting structure.

Optionally, in the touch-control display panel according to embodiments of the present disclosure, the first protective layer is between the optical adjusting structure and the touch-control structure layer, and a second protective layer is between the first protective layer and the touch-control structure layer.

Optionally, in the touch-control display panel according to embodiments of the present disclosure, a thickness of the first protective layer and a thickness of the second protective layer are both less than 2 μm.

Optionally, in the touch-control display panel according to embodiments of the present disclosure, the display panel further includes a third protective layer between the second protective layer and the touch-control structure layer, a boundary of an orthographic projection of the third protective layer on the substrate includes a third boundary in the transition region, the third boundary is between the second boundary and the display region, and a distance between the third boundary and the second boundary is greater than or equal to the preset distance.

Optionally, in the touch-control display panel according to embodiments of the present disclosure, along a direction of the substrate pointing to the touch-control structure layer, a thickness of the first protective layer is greater than a thickness of the second protective layer, and the thickness of the second protective layer is greater than a thickness of the third protective layer.

Optionally, in the touch-control display panel according to embodiments of the present disclosure, the at least two protective layers are organic material layers.

Optionally, in the touch-control display panel according to embodiments of the present disclosure, the preset distance is greater than or equal to 50 μm.

Optionally, in the touch-control display panel according to embodiments of the present disclosure, the display structure layer includes a driving array layer between the substrate and the encapsulating layer, and a light emitting structure layer between the driving array layer and the encapsulating layer;
the driving array layer includes a first source-drain metal layer and a second source-drain metal layer stacked, the first metal lapping electrode and the second source-drain metal layer are on the same layer.

Optionally, in the touch-control display panel according to embodiments of the present disclosure, the bonding region further includes a second metal lapping electrode between the substrate and the first metal lapping electrode and insulated from the substrate and the first metal lapping electrode, the second metal lapping electrode and the first source-drain metal layer are on the same layer, the first metal lapping electrode and the second metal lapping electrode are connected through a via hole.

Optionally, in the touch-control display panel according to embodiments of the present disclosure, the optical adjusting structure includes a color film layer and a black matrix layer; the color film layer includes a plurality of color films of different colors on the same layer and sequentially and circularly arranged, the black matrix layer has a plurality of openings, the color films are in the openings;
orthographic projections of adjacent color films on the substrate are overlapped or not overlapped;
the color films correspond to light emitting regions in the light emitting structure layer, the color films are used for transmitting light emitted from the light emitting regions through corresponding color films.

Correspondingly, embodiments of the present disclosure further provide a display device including the touch-control display panel according to embodiments of the present disclosure.

Correspondingly, embodiments of the present disclosure further provide a manufacturing method for a touch-control display panel, including:
providing a substrate, where the substrate is divided into a display region and a peripheral region surrounding the display region, the peripheral region includes a first frame region at one side of the display region, the first frame region includes a bonding region and a transition region between the bonding region and the display region;
manufacturing a display structure layer in the display region of the substrate;
manufacturing an encapsulating layer on one side of the display structure layer away from the substrate, and manufacturing a metal lapping hole in the bonding region;
manufacturing an optical adjusting structure on one side of the encapsulating layer away from the substrate;
manufacturing at least two protective layers on one side of the optical adjusting structure away from the substrate, where orthographic projections of the at least two protective layers on the substrate cover the display region and at least cover a part of the first frame region, the orthographic projection of the at least two protective layers on the substrate and an orthographic projection of the metal lapping hole on the substrate do not overlap, and a distance between boundaries of the orthographic projections of the at least two protective layers in the first frame region is greater than or equal to a preset distance; and
manufacturing a touch-control structure layer on one side of the at least two protective layers away from the substrate; where the touch-control structure layer includes a touch-control electrode lead, and at least a part of the touch-control electrode lead covers the metal lapping hole.

### BRIEF DESCRIPTION OF FIGURES

FIG. 1 is a schematic structural diagram of a touch-control display panel in related art;

FIG. 2 is a plane structure diagram of a touch-control display panel according to an embodiment of the present disclosure;

FIG. 3 is a schematic diagram of a cross-sectional structure of part of sub-pixels in FIG. 2;

FIG. 4 is a schematic diagram of a cross-sectional structure along a direction of CC′ in FIG. 2 in the related art;

FIG. 5 is a schematic diagram of a cross-sectional structure of a touch-control display panel according to an embodiment of the present disclosure;

FIG. 6 is a schematic diagram of a cross-sectional structure along a direction of CC′ in FIG. 2 according to an embodiment of the present disclosure;

FIG. 7 is another schematic diagram of a cross-sectional structure along a direction of CC′ in FIG. 2 according to an embodiment of the present disclosure;

FIG. 8 is another schematic diagram of a cross-sectional structure along a direction of CC′ in FIG. 2 according to an embodiment of the present disclosure;

FIG. 9 is another schematic diagram of a cross-sectional structure along a direction of CC′ in FIG. 2 according to an embodiment of the present disclosure;

FIG. 10 is another schematic diagram of a cross-sectional structure along a direction of CC′ in FIG. 2 according to an embodiment of the present disclosure;

FIG. 11 is another schematic diagram of a cross-sectional structure along a direction of CC′ in FIG. 2 according to an embodiment of the present disclosure;

FIG. 12 is another schematic diagram of a cross-sectional structure along a direction of CC′ in FIG. 2 according to an embodiment of the present disclosure;

FIG. 13 is another schematic diagram of a cross-sectional structure along a direction of CC′ in FIG. 2 according to an embodiment of the present disclosure;

FIG. 14 is another schematic diagram of a cross-sectional structure along a direction of CC′ in FIG. 2 according to an embodiment of the present disclosure;

FIG. 15 is another schematic diagram of a cross-sectional structure along a direction of CC′ in FIG. 2 according to an embodiment of the present disclosure;

FIG. 16 is another schematic diagram of a cross-sectional structure along a direction of CC′ in FIG. 2 according to an embodiment of the present disclosure;

FIG. 17 is a schematic flow chart of a manufacturing method for a touch-control display panel according to an embodiment of the present disclosure;

FIG. 18 is a schematic structural diagram of a display device according to an embodiment of the present disclosure.

### DETAILED DESCRIPTION

For making objectives, technical solutions and advantages of the present disclosure clearer, specific implementations of the touch-control display panel and the display device according to embodiments of the present disclosure will be clearly described below in conjunction with accompanying drawings. It should be understood that embodiments described below are only for illustration and explanation of the present disclosure, and are not intended to limit the present disclosure. Embodiments in the present disclosure and features of embodiments may be combined with each other without conflict.

Thickness, size, and shape of a thin film of each layer in the accompanying drawings do not reflect the true proportion of the touch-control display panel, and are only intended to illustrate the present disclosure.

At present, a Polarizer (POL) can effectively reduce reflectivity of a display panel under strong light, but lose more light emitted. This greatly increases the lifetime burden for the OLED display panel. Moreover, a thickness of the polarizer is large and a material of the polarizer is brittle, which is not conducive to realization of flexible display characteristics such as folding and curling of the OLED display panel. Based on the above problem, a color filter is currently used instead of the polarizer. However, there are many problems in the panel fabrication process using the color filter instead of the polarizer. For example, a thickness of an encapsulation structure between a display structure layer and a color filter is large, which is not conducive to achieving a thin display panel. Moreover, it is not conducive to improvement of the brightness attenuation (L-Decay) angle.

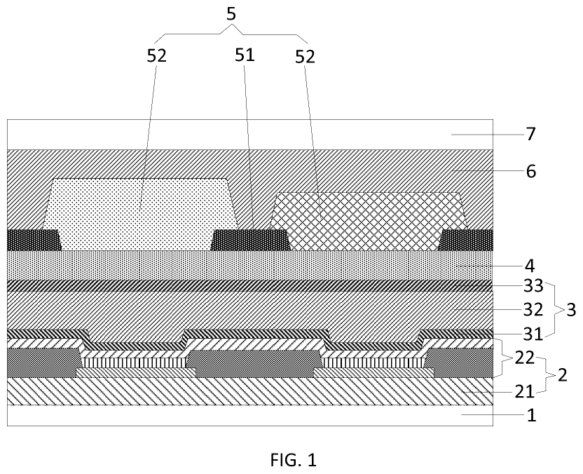

FIG. 1 is a schematic structural diagram of a display panel in the related art. As shown in FIG. 1, the display panel includes a substrate 1, a display structure layer 2 (including a driving array layer 21 and a light emitting structure layer 22) arranged on the substrate 1, an encapsulation structure layer 3, a touch-control structure layer 4, an optical adjusting structure 5 (for example, including a black matrix layer 51 and a color film 52), a protective layer 6, and a cover plate 7. The encapsulation structure layer 3 includes a first inorganic layer 31, an organic layer 32, and a second inorganic layer 33 stacked from bottom to top. The optical adjusting structure 5 and the subsequent process of forming the protective layer 6 (such as etching process) are easy to damage the touch-control structure layer 4, which is not conducive to connection of touch leads of the touch-control structure layer 4.

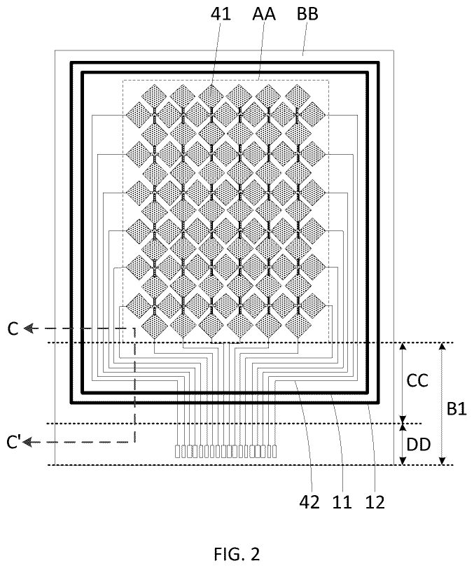

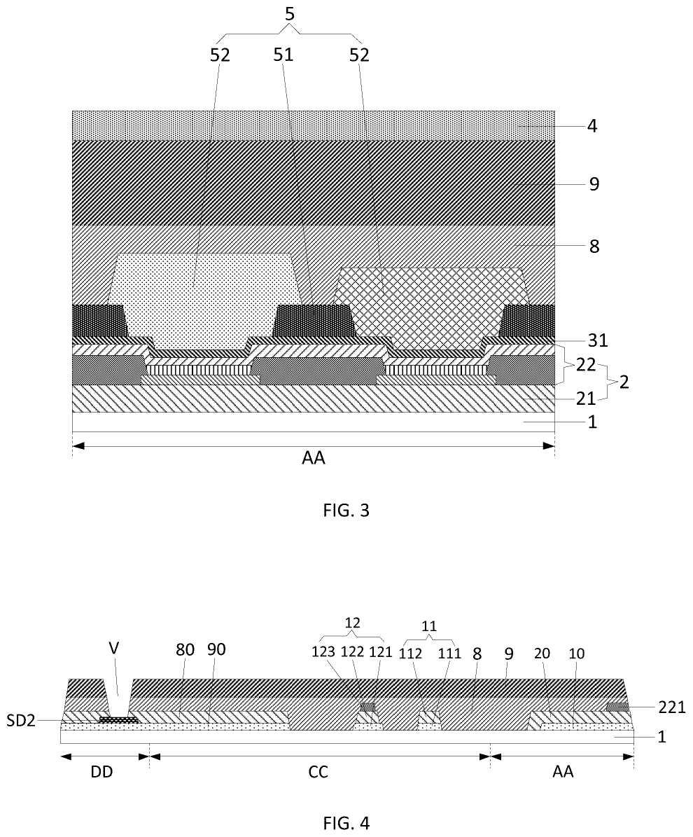

As shown in FIG. 2 and FIG. 3, FIG. 2 is a plane structural diagram of an OLED display panel according to an embodiment of the present disclosure. The display panel includes a display region AA and a peripheral region BB surrounding the display region AA. The peripheral region BB includes a first frame region B1 (lower frame) located at one side of the display region AA. The first frame region B1 includes a bonding region DD and a transition region CC between the bonding region DD and the display region AA. The display region AA generally includes a plurality of light emitting sub-pixels. As shown in FIG. 3, FIG. 3 is a schematic diagram of a cross-sectional structure of part of light emitting sub-pixels in FIG. 2. The display panel includes a substrate 1, a display structure layer 2 (including a driving array layer 21 and a light emitting structure layer 22) arranged on the substrate 1), an encapsulating layer (equivalent to the first inorganic layer 31 in FIG. 1), an optical adjusting structure 5 (including a black matrix layer 51 and/or a color film 52), a first protective layer 8, a second protective layer 9, and a touch-control structure layer 4.

A film thickness of the encapsulation structure layer 3 (especially an organic layer 32) is large, which is not conducive to realization of a thin display panel. A distance between the display structure layer 2 and the optical adjusting structure 5 is relatively large, which is not conducive to raising the L-Decay angle. However, if a film thickness of the organic layer 32 is directly reduced, leveling performance of the second inorganic layer 33 is inevitably deteriorated, causing the problem of uneven display brightness of partial regions and the like. In some embodiments of the present disclosure, the encapsulation structure layer 3 shown in FIG. 1 in the related art is no longer used, an encapsulating layer 31 of a single film layer design is used on the display structure layer 2. After the encapsulating layer 31, the optical adjusting structure 5 is manufactured first, and then the touch-control structure layer 4 is manufactured. In this way, the encapsulating layer 31 can not only encapsulate the display structure layer 2, but also improve the water and oxygen resistance of the display panel. Moreover, a distance between the optical adjusting structure 5 and the light emitting structure layer 22 can be reduced, and a film thickness of the display panel can be reduced, raising the L-Decay angle. Of course, the encapsulation structure layer 3 shown in FIG. 1 in the related art may also be used in some embodiments of the present disclosure.

The first protective layer 8 in some embodiments of the present disclosure mainly plays a role of planarization. The light emitting structure layer 22 includes a pixel defining layer having a pixel opening, and an anode, a light emitting layer and a cathode in the pixel opening. If a distance between the cathode and the touch-control structure layer 4 is too close, a cathode signal may interfere with a touch control signal of the touch-control structure layer 4. Therefore, in order to ensure touch-control performance, a second protective layer 9 is required to be disposed between the first protective layer 8 and the touch-control structure layer 4.

As shown in FIG. 2, the touch-control structure layer 4 includes a plurality of touch-control electrodes 41 and a plurality of touch-control electrode leads 42 in the display region AA. The touch-control electrode leads 42 are electrically connected with corresponding touch-control electrode rows or touch-control electrode columns. The touch-control electrode leads 42 extend from the display region AA to the bonding region DD. As shown in FIG. 4 which is a schematic diagram of a cross-sectional structure along a direction of CC′in FIG. 2, the bonding region DD includes a bending region, to bend a driving IC and the like to a back surface of the display panel. In order to improve bending performance of the bending region, the touch-control electrode leads 42 need to be jumped to a source-drain metal layer (such as an SD2 layer) in the driving array layer 21. Therefore, the first protective layer 8, the second protective layer 9, and the planarization layer above the bending region need to be subjected to a via process to form a metal lapping hole V. Because a thickness of the first protective layer 8 and the second protective layer 9 is thicker, the metal lapping hole V is deeper. The touch-control electrode lead 42 is formed by a photoresist process. When forming the touch-control electrode lead 42, a whole layer of a metal layer is deposited first, then a photoresist is coated on the whole layer of the metal layer. Because the metal lapping hole V is deeper and the photoresist is accumulated thicker at the metal lapping hole V, the photoresist is difficult to be effectively removed by exposure and development, so that the photoresist is remained in the metal lapping hole V, and poor etching is further caused, to form metal residues in the metal lapping hole V, and the residual metal causes a short circuit between the touch-control electrode leads 42, and product yield is reduced.

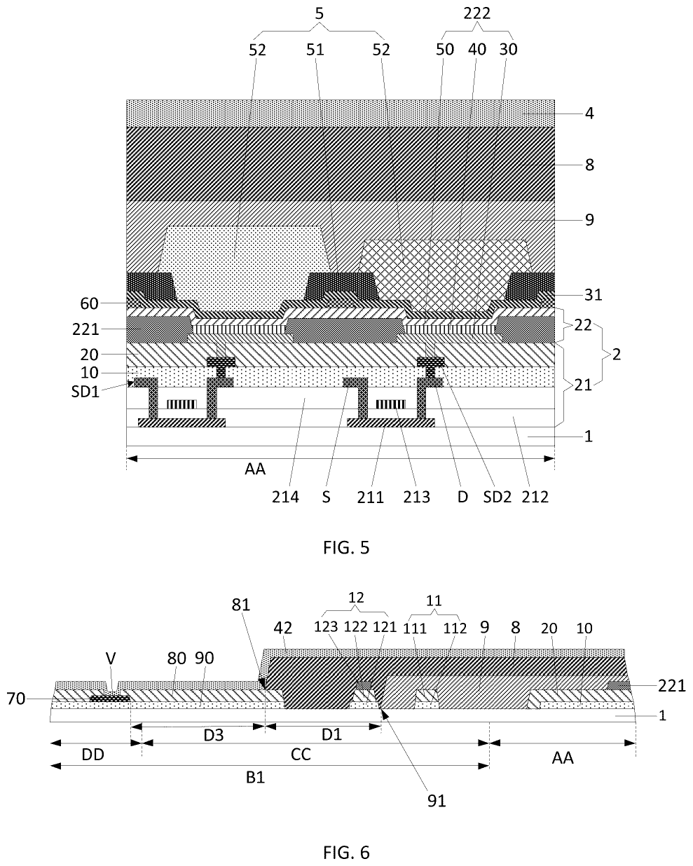

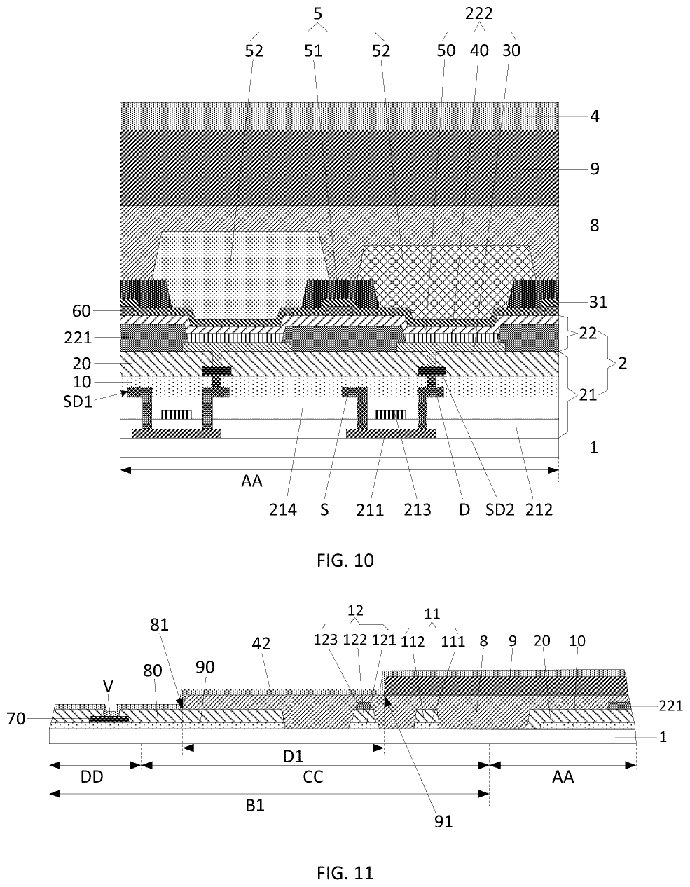

In order to solve the above technical problem, an embodiment of the present disclosure provides a touch-control display panel, as shown in FIGS. 2, 3 and 5 to 15. FIG. 5 and FIG. 10 are respectively two detailed cross-sectional views of the display region in FIG. 2. FIG. 6 to FIG. 9 and FIG. 11 to FIG. 15 are cross-sectional views in a direction of CC′ in FIG. 2. The touch-control display panel includes a display region AA and a peripheral region BB surrounding the display region AA. The peripheral region BB includes a first frame region B1 at one side of the display region AA. The first frame region B1 includes a bonding region DD and a transition region CC between the bonding region DD and the display region AA.

The touch-control display panel includes: a substrate 1; a display structure layer 2 arranged on the substrate 1 and located in the display AA region; an encapsulating layer 31 on one side of the display structure layer 2 away from the substrate 1, and at least a part of the encapsulating layer 31 is located in the display region AA; an optical adjusting structure 5 on one side of the encapsulating layer 31 away from the substrate 1; a metal lapping hole V disposed on the substrate 1 and located in the bonding region DD; at least two protective layers (8 and 9) on one side of the optical adjusting structure 5 away from the substrate 1, where orthographic projections of the at least two protective layers (8 and 9) on the substrate 1 cover the display region AA and at least cover a part of the first frame region B1, the orthogonal projection of the at least two protective layers (8 and 9) on the substrate 1 and an orthogonal projection of the metal lapping hole V on the substrate 1 do not overlap, and a distance D1 between boundaries of orthographic projections of the at least two protective layers (8 and 9) in the first frame region B1 is greater than or equal to a preset distance; a touch-control structure layer 4 on one side of the at least two protective layers (8 and 9) away from the substrate 1, where the touch-control structure layer 4 includes a touch-control electrode lead 42 extending from the display region AA to the bonding region DD through the transition region CC, and at least a part of the touch-control electrode lead 42 covers the metal lapping hole V.

According to the touch-control display panel according to an embodiment of the present disclosure, the second protective layer is arranged between the first protective layer and the touch structural layer, the touch-control performance can be ensured. In addition, according to the present disclosure, the distance between the boundaries of the orthographic projection of at least two protective layers in the first frame region is set to be greater than or equal to the preset distance. In this way, it can be avoided that the distance between the boundaries of the orthographic projections of the at least two protective layers in the first frame region is too close to cause the problem that heights of the at least two protective layers at boundary positions are too high. When a photoresist process is adopted to manufacture the touch-control electrode lead, no metal residue is generated in the metal lapping hole, to ensure the touch-control performance.

In a specific implementation, in the above touch-control display panel according to an embodiment of the present disclosure, as shown in FIG. 5 and FIG. 10, the display structure layer 2 includes a driving array layer 21 between the substrate 1 and the encapsulating layer 31, and a light emitting structure layer 22 between the driving array layer 21 and the encapsulating layer 31. The driving array layer 21 may include functional structures such as gate lines, data lines, power lines, thin film transistor arrays, and storage capacitors. FIG. 5 and FIG. 6 show a specific structure of a thin film transistor array. The thin film transistor array includes an active layer 211, a gate insulating layer 212, a gate electrode 213, an interlayer insulating layer 214, a source-drain metal layer SD1 (including a source electrode S and a drain electrode D), a first planarization layer 10, a second source-drain metal layer SD2, and a second planarization layer 20 between a substrate 1 and a light emitting structure layer 22. The light emitting structure layer 22 may include a pixel defining layer 221 and sub-pixel regions 222 defined by the pixel defining layer 221. Each of the sub-pixel regions 222 may include an anode layer 30, a light emitting layer 40 and a cathode layer 50 in sequence from a side close to the driving array layer 21 to a side away from the driving array layer 21. The anode layer 30 is electrically connected with the second source-drain metal layer SD2 through a via hole penetrating through the second planarization layer 20. The second source-drain metal layer SD2 is electrically connected with the drain electrode D through a via hole penetrating through the first planarization layer 10.

In a specific implementation, in the above touch-control display panel according to an embodiment of the present disclosure, as shown in FIG. 5 and FIG. 10, the optically adjusting structure 5 may for example include a color film layer 52 and/or a black matrix layer 51. The color film layer 52 includes a plurality of color films (for example, R, G, B) of different colors on the same layer and sequentially and circularly arranged. The black matrix layer 51 has a plurality of openings, and the color films (such as R, G, and B) are disposed in corresponding openings. FIG. 5 and FIG. 10 of embodiments of the present disclosure only illustrate a red color film R and a blue color film B.

Orthographic projections of adjacent color films (such as R and B) on the substrate 1 are overlapped or not overlapped. In an embodiment of the present disclosure, for example, the orthographic projections of the adjacent color films 52 on the substrate 1 are not overlapped.

The color films (e.g. R, G, B) correspond to light emitting regions in the light emitting structure layer 2. The color films (such as R, G, and B) are used for transmitting light emitted by the light emitting regions through corresponding color films. Of course, in some embodiments, the optical adjusting structure 5 may include one of the color film layer 52 or the black matrix layer 51, for example.

In a specific implementation, as shown in FIG. 5 and FIG. 10, the touch-control structure layer 4 may include a first insulating layer, a first touch-control electrode layer, a second insulating layer, and a second touch-control electrode layer stacked. The first touch-control electrode layer may include a plurality of bridge electrodes, the second touch-control electrode layer may include a plurality of touch-control electrodes. One parts of the touch-control electrodes are directly and electrically connected through a connecting part in the second touch-control electrode layer. The other parts of the touch-control electrodes are electrically connected through the bridging electrode in the first touch-control electrode layer. Tx touch-control electrodes and Rx touch-control electrodes are obtained. A Tx touch-control electrode row and A Rx touch-control electrode column are respectively electrically connected with corresponding touch-control electrode leads respectively.

In a specific implementation, in the above touch-control display panel according to an embodiment of the present disclosure, the touch-control electrode lead may be disposed on the same layer as the first touch-control electrode layer or the second touch-control electrode layer. In order to reduce the resistance, two layers of touch-control electrode leads electrically connected may be disposed on the first touch-control electrode layer and the second touch-control electrode layer.

Optionally, as shown in FIG. 5 and FIG. 10, the substrate 1 may include a polyimide layer and a buffer layer sequentially stacked.

In a specific implementation, in the above touch-control display panel according to an embodiment of the present disclosure, as shown in FIG. 5 and FIG. 10, the touch-control display panel further includes a spacer 60 between the cathode layer 50 and the encapsulating layer 31. Of course, other functional film layers known to those skilled in the art may also be included, and will not be described in detail herein.

In a specific implementation, in the above touch-control display panel according to an embodiment of the present disclosure, as shown in FIGS. 2, 6 to 9 and 11 to 15, the touch-control display panel further includes a first blocking dam 11 and a second blocking dam 12 in the transition region CC and spaced apart. The first blocking dam 11 surrounds a periphery of the display region AA. The second blocking dam 12 surrounds a periphery of the first blocking dam 11.

The at least two protective layers (8 and 9) include a first protective layer 8. A boundary of an orthographic projection of the first protective layer 8 on the substrate 1 includes a first boundary 81 in the first frame region B1. The first boundary 81 is on one side of the second blocking dam 12 away from the first blocking dam 11. In this way, a position of a second boundary 91 of a second protective layer 9 can be reasonably set, so that a distance D1 between the first boundary 81 and the second boundary 91 is greater than or equal to a preset distance. In this way, it can be avoided that the distance D1 between the boundaries of the orthographic projections of the first protective layer 8 and the second protective layer 9 in the first frame region B1 is too close to cause the problem that heights of the first protective layer 8 and the second protective layer 9 at boundary positions are too high. When the touch-control electrode lead 42 is manufactured by using a photoresist process, no metal residue is generated in the metal lapping hole V, to ensure the touch-control performance.

In some embodiments, a distance D1 between the first boundary 81 and the second boundary 91 is greater than or equal to a preset distance. For example, the preset distance is from 0.25 μm to 15 μm. For example, the preset distance D1 between the first boundary 81 and the second boundary 91 is 0.25 μm, 10 μm, 15 μm, 30 μm, 50 μm, etc.

In some embodiments, the distance D1 between the first boundary 81 and the second boundary 91 is less than a distance D3 between the metal landing hole V and at least one of the first boundary 81 or the second boundary 91. As shown in FIG. 6, the distance D1 between the first boundary 81 and the second boundary 91 is less than the distance D3 between the metal lapping hole V and the first boundary 81. Such a design is beneficial to ensuring that there is enough space between the touch-control electrode lead 42 and the metal lapping hole V to connect the first metal lapping electrode 70. In some embodiments, a distance between the second boundary 91 and the second blocking dam 12 is less than a distance between the second boundary 91 and the first blocking dam 11. As shown in FIG. 6, the distance between the second boundary 91 and the second blocking dam 12 is less than the distance between the second boundary 91 and the first blocking dam 11. Such a design is beneficial to ensuring planarization of the first protective layer 8 and the second protective layer 9 between the first blocking dam 11 and the second blocking dam 12.

In a specific implementation, in the above touch-control display panel according to an embodiment of the present disclosure, as shown in FIG. 5 to FIG. 15, the first blocking dam 11 and the second blocking dam 12 may be formed by sub-blocking dams stacked on the same layer as a first planarization layer 10, a second planarization layer 20, a pixel defining layer 221 and the like in the display region AA. For example, the first blocking dam 11 is formed by sub-blocking dams (111 and 112) on the same layer as the first planarization layer 10 and the second planarization layer 20 in the display region. The second blocking dam 12 is formed by sub-blocking dams (121, 122 and 123) on the same layer as the first planarization layer 10, the second planarization layer 20 and the pixel defining layer 221 in the display region. Generally, a height of the first blocking dam 11 adjacent to the display region AA is less than a height of the second blocking dam 12. Of course, the height of the first blocking dam 11 may also be equal to the height of the second blocking dam 12.

In a specific implementation, in the above touch-control display panel according to an embodiment of the present disclosure, as shown in FIGS. 2, 6 to 9 and 11 to 15, the bonding region DD includes a first metal lapping electrode 70 on the substrate 1, the first frame region B1 includes a first planarization structure 80 on one side of the first metal lapping electrode 70 away from the substrate 1. An orthographic projection of the first planarization structure 80 on the substrate 1 covers the bonding region DD and a part of the transition region CC. The first planarization structure 80 and the second blocking dam 12 are spaced apart. The first planarization structure 80 includes a metal lapping hole V, and an orthographic projection of the metal lapping hole V on the substrate 1 is within a range of an orthographic projection of the first metal lapping electrode 70 on the substrate 1. Of course, the first planarization structure 80 can also include a plurality of metal lapping holes V.

The first boundary 81 is at least within an edge of the orthographic projection of the first planarization structure 80 on the substrate 1. This makes it possible for the first protective layer 8 to cover an edge region of the first planarization structure 80, so that the first boundary 81 of the first protective layer 8 is not too high. Therefore, the risk of metal residue when manufacturing the touch-control electrode lead 42 can be reduced.

In a specific implementation, in the above touch-control display panel according to an embodiment of the present disclosure, as shown in FIGS. 5 to 13, the first planarization structure 80 may be on the same layer as the second planarization layer 20 in the display region AA.

In a specific implementation, in the above touch-control display panel according to an embodiment of the present disclosure, as shown in FIGS. 2, 6 to 9 and 11 to 15, the first frame region B1 further includes a second planarization structure 90 between the substrate 1 and the first planarization structure 80. An orthographic projection of the second planarization structure 90 on the substrate 1 covers the bonding region DD and a part of the transition region CC. The second planarization structure 90 is spaced from the second blocking dam 12. The second planarization structure 90 may be on the same layer as the first planarization layer 10 in the display region AA.

In a specific implementation, in the above touch-control display panel according to an embodiment of the present disclosure, as shown in FIGS. 6 to 9 and 11 to 15, the at least two protective layers (8 and 9) further include a second protective layer 9. A boundary of an orthographic projection of the second protective layer 9 on the substrate 1 includes a second boundary 91 in the first frame region B1.

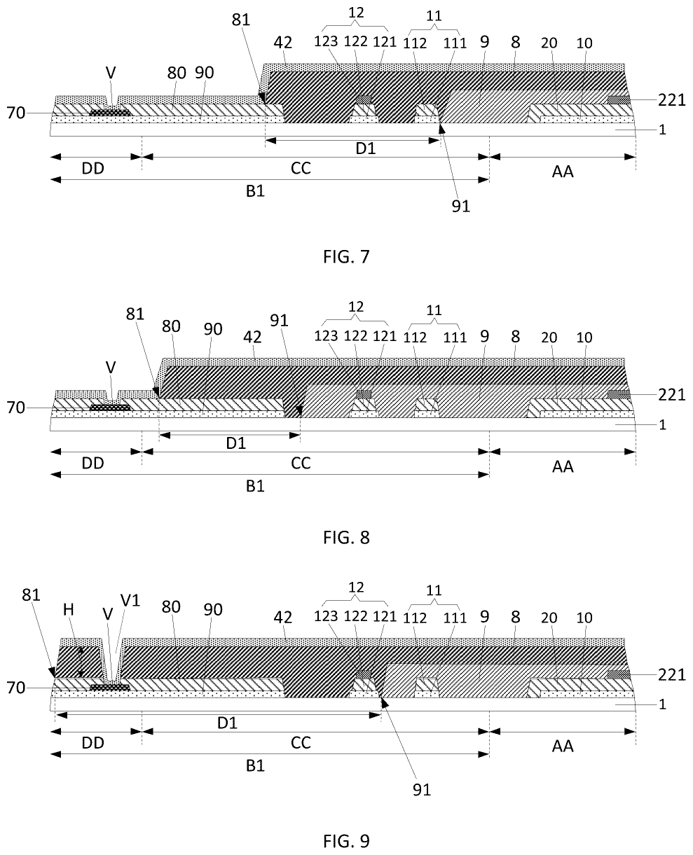

In a specific implementation, in the above touch-control display panel according to an embodiment of the present disclosure, as shown in FIGS. 8 and 11 to 13, the second boundary 91 is on one side of the second blocking dam 12 close to the display region AA. As shown in FIG. 7, the second boundary 91 is on one side of the first blocking dam 11 close to the display region AA. This makes it possible that the distance D1 between the first boundary 81 and the second boundary 91 is not too small, so that a boundary height of the first protective layer 8 on an edge of the first planarization structure 80 is not too high. This is equivalent to removing the first protective layer 8 from the first boundary 81 to the bonding region DD and in the bonding region DD. The metal landing hole V is only equivalent to a shallow hole penetrating the first planarization structure 80. Therefore, the problem of residual metal in the metal lapping hole V when manufacturing the touch-control electrode lead 42 can be avoided.

In a specific implementation, in the above touch-control display panel according to an embodiment of the present disclosure, as shown in FIGS. 8 and 11 to 13, the first boundary 81 is at least close to the metal landing hole V. The second boundary 91 is between the first planarization structure 80 and the display region AA. This may ensure that the distance D1 between the first boundary 81 and the second boundary 91 is greater than or equal to a preset distance. This is equivalent to removing the second protective layer 9 from the second boundary 91 to the bonding region DD and in the bonding region DD, and removing the first protective layer 8 above the metal lapping hole V. The metal landing hole V is only equivalent to a shallow hole penetrating the first planarization structure 80. Therefore, the problem of residual metal in the metal lapping hole V when manufacturing the touch-control electrode lead 42 can be avoided.

It should be noted that the second boundary 91 in FIG. 8 is between the first planarization structure 80 and the second blocking dam 12, for example. Of course, the second boundary 91 may also be between the first blocking dam 11 and the second blocking dam 12, or between the first blocking dam 11 and the display region AA.

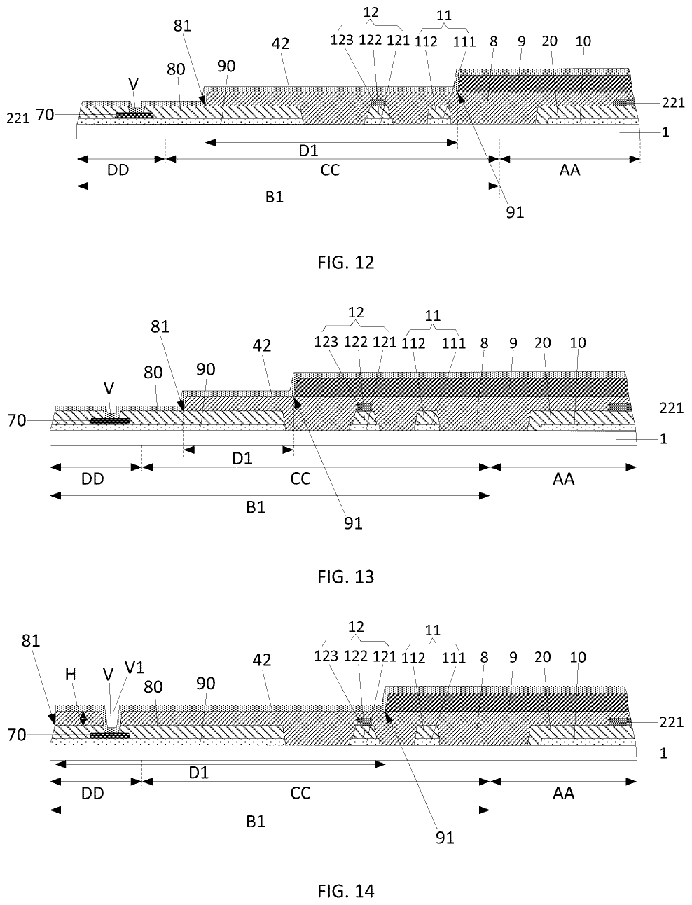

As shown in FIG. 11, the second boundary 91 is between the first blocking dam 11 and the second blocking dam 12. As shown in FIG. 12, the second boundary 91 is between the first blocking dam 11 and the display region AA. As shown in FIG. 13, the second boundary 91 is between the first planarization structure 80 and the second blocking dam 12.

In some embodiments, as shown in FIGS. 11 to 13, in a direction from the display region AA to the bonding region DD, the touch-control electrode lead 42 forms a stepped structure. By gradually reducing a height from the touch-control electrode lead 42 to the metal lapping hole V, it is beneficial to avoid the risk of disconnection caused by an excessive height difference between the touch-control electrode lead 42 and the metal lapping hole V. For example, a distance from the second boundary 91 to the first boundary 81 is greater than or equal to a distance from the first boundary 81 to the metal lapping hole V.

It should be noted that the first boundary 81 in FIGS. 10 and 11 may also be within an edge of an orthographic projection of the first planarization structure 80 on the substrate 1.

In a specific implementation, in the above touch-control display panel according to an embodiment of the present disclosure, as shown in FIG. 9 and FIG. 14, the first boundary 81 is on one side of the metal lapping hole V away from the display region AA. The first protective layer 8 has a first via hole V1. An orthographic projection of the first via hole V1 on the substrate 1 covers the orthographic projection of the metal lapping hole V on the substrate 1. The second boundary 91 is between the first planarization structure 80 and the display region AA. This may ensure that the distance D1 between the first boundary 81 and the second boundary 91 is greater than or equal to a preset distance. Only the first protective layer 8 is covered above the metal lapping hole V. The overall depth of the metal landing hole V and the first via hole V1 is not too deep compared to the depth of the via hole shown in FIG. 3. Therefore, the risk of residual metal in the metal lapping hole V can also be reduced.

It should be noted that the second boundary 91 in FIG. 9 and FIG. 14 is between the first blocking dam 11 and the second blocking dam 12, for example. Of course, the second boundary 91 may also be between the first planarization structure 80 and the second blocking dam 12, and may also be between the first blocking dam 11 and the display region AA.

In a specific implementation, in the above touch-control display panel according to an embodiment of the present disclosure, as shown in FIG. 9 and FIG. 14, a thickness H of the first protective layer 8 in a region of the metal lapping hole V is less than 3 μm. This may further reduce the overall depth of the metal landing hole V and the first via hole V1, to further reduce the risk of residual metal in the metal lapping hole V.

In a specific implementation, in the above touch-control display panel according to an embodiment of the present disclosure, as shown in FIGS. 5 to 9, the first protective layer 8 is between the optical adjusting structure 5 and the touch-control structure layer 4. The second protective layer 9 is between the first protective layer 8 and the optical adjusting structure 5.

In a specific implementation, in the above touch-control display panel according to an embodiment of the present disclosure, as shown in FIGS. 10 to 14, the first protective layer 8 is between the optical adjusting structure 5 and the touch-control structure layer 4. The second protective layer 9 is between the first protective layer 8 and the touch-control structure layer 4.

In a specific implementation, in the above touch-control display panel according to an embodiment of the present disclosure, as shown in FIGS. 10 to 14, a thickness of the first protective layer 8 and a thickness of the second protective layer 8 are both less than 2 μm. This may further reduce the risk of residual metal in the metal lapping hole V.

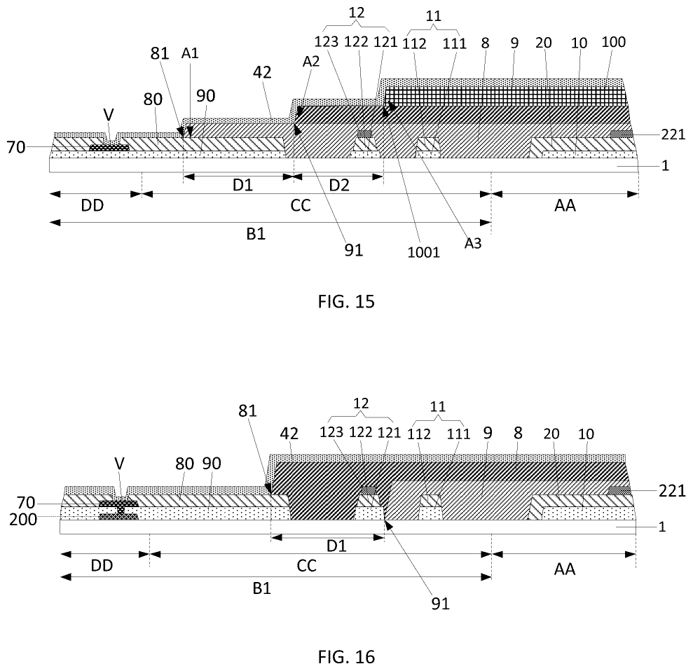

In a specific implementation, in the above touch-control display panel according to an embodiment of the present disclosure, as shown in FIG. 10 and FIG. 15, the display panel further includes a third protective layer 100 between the second protective layer 9 and the touch-control structure layer 4. A boundary of an orthographic projection of the third protective layer 100 on the substrate 1 includes a third boundary 1001 in the transition region CC. The third boundary 1001 is between the second boundary 91 and the display region AA. A distance D2 between the third boundary 1001 and the second boundary 91 is greater than or equal to the preset distance. Therefore, thicknesses of the first protective layer 8, the second protective layer 9 and the third protective layer 100 can be made thinner (for example, all less than 2 μm). On the basis of ensuring the touch-control performance, slopes of the film layers corresponding to every two adjacent boundaries in the first frame region B1 are gentle, to further reduce the risk of residual metal in the metal lapping hole V.

In a specific implementation, in the above touch-control display panel according to an embodiment of the present disclosure, as shown in FIG. 15, along a direction of the substrate 1 pointing to the touch-control structure layer 4, a thickness of the first protective layer 8 is greater than a thickness of the second protective layer 9, and the thickness of the second protective layer 9 is greater than a thickness of the third protective layer 100. Of course, the thickness of the first protective layer 8, the thickness of the second protective layer 9, and the thickness of the third protective layer 100 may be the same.

In some embodiments, as shown in FIG. 15, in a direction of the touch-control electrode lead 42 from the bonding region DD to the display region AA, slope angles of the first protective layer 8, the second protective layer 9, and the third protective layer 100 may be gradually decreased. The slope angle is an included angle formed by a protective layer and a horizontal plane (for example, parallel to the substrate 1). For example, a slope angle A1 of the first protective layer 8 is an included angle A1 formed by the first protective layer 8 and the first planarization structure 80. A slope angle A1 of the second protective lay 9 is an included angle A2 formed by the second protective layer 9 and the first protective layer 8. A slope angle of the third protective layer 100 is an included angle A3 formed by the third protective layer 100 and the second protective layer 9. It is beneficial to ensure that a contact surface between the touch-control electrode lead 42 and a corresponding protective layer is gentler and is not easy to break.

In some embodiments, as shown in FIG. 15, in a direction of the touch-control electrode lead 42 from the display region AA to the bonding region DD, a thickness of the touch-control electrode lead 42 forms a step structure. By gradually reducing the thickness of the touch-control electrode lead 42, flexibility of the touch-control electrode lead 42 can be increased. It is beneficial to ensure that the contact surface between the touch-control electrode lead 42 and the corresponding protective layer is more gentle and tough, and is not easy to break.

In some embodiments, as shown in FIG. 15, in a direction of the touch-control electrode lead 42 from the display region AA to the bonding region DD, a step structure is formed from a surface of the touch-control electrode lead 42 to a height of the metal lapping hole V. By gradually reducing the height from the touch-control electrode lead 42 to the metal lapping hole V, it is beneficial to avoid the risk of disconnection caused by the excessive height difference between the touch-control electrode lead 42 and the metal lapping hole V. For example, the distance from the third boundary 1001 to the second boundary 91 is greater than or equal to the distance from the second boundary 91 to the first boundary 81, and is greater than or equal to the distance from the first boundary 81 to the metal landing hole V.

In a specific implementation, in the above touch-control display panel according to an embodiment of the present disclosure, as shown in FIGS. 5 to 15, the first protective layer 8, the second protective layer 9, and the third protective layer 100 can all be organic material layers. For example, the organic material layer is an OC layer. Since the OC layer is a low temperature material, the influence of the high temperature process on the display structure layer 2 can be avoided.

In some embodiments, in the above touch-control display panel according to an embodiment of the present disclosure, the preset distance may be greater than or equal to 50 μm.

In a specific implementation, in the above touch-control display panel according to an embodiment of the present disclosure, as shown in FIGS. 5 to 15, the first metal lapping electrode 70 may be on the same layer as the second source-drain metal layer SD2. In this way, it is only necessary to change the original composition pattern when forming the second source-drain metal layer SD2. The first metal lapping electrode 70 and the second source-drain metal layer SD2 can be patterned by one patterning process. A process for separately preparing the first metal lapping electrode 70 is not required to be added, the preparation process flow can be simplified, the production cost is saved, and the production efficiency is improved.

In a specific implementation, in the above touch-control display panel according to an embodiment of the present disclosure, as shown in FIGS. 5 to 15, the bonding region DD has the first metal lapping electrode 70 on the same layer as the second source-drain metal layer SD2, for example. In order to reduce the resistance of the touch-control electrode lead 42, as shown in FIG. 16, the bonding region DD may further include a second metal lapping electrode 200 between the substrate 1 and the first metal lapping electrode 70 and insulated from the substrate 1 and the first metal lapping electrode 70. The second metal lapping electrode 200 is on the same layer as the first source-drain metal layer SD1 in the display region AA of FIG. 5. The first metal lapping electrode 70 and the second metal lapping electrode 200 may be connected through a via hole.

Of course, in a specific implementation, in order to further reduce the narrow frame design, the touch-control display panel according to an embodiment of the present disclosure may further include a first source-drain metal layer, a second source-drain metal layer and a third source-drain metal layer sequentially stacked. When the bonding region only includes the first metal lapping electrode, the first metal lapping electrode may be in the first source-drain metal layer, or the first metal lapping electrode may be in the second source-drain metal layer, or the first metal lapping electrode may also be in the third source-drain metal layer. When the bonding region includes a first metal lapping electrode and a second metal lapping electrode electrically connected, the first metal lapping electrode may be in any one of the first source-drain metal layer, the second source-drain metal layer or the third source drain material layer, and the second metal lapping electrode is in another source-drain metal layer. When the bonding region includes a first metal lapping electrode, a second metal lapping electrode and a third metal lapping electrode electrically connected in sequence, the first metal lapping electrode may be in the first source-drain metal layer, the second metal lapping electrode may be in the second source-drain metal layer, and the third metal lapping electrode may be in the third source-drain metal layer.

In a specific implementation, in the above touch-control display panel according to an embodiment of the present disclosure, as shown in FIGS. 2, and 5 to 16, because the metal lapping hole V needs to be arranged in the bonding region DD of the first frame region B1, in order to reduce the risk of residual metal (the metal layer for manufacturing the touch-control electrode lead) in the metal lapping hole V, the first protective layer 8, the second protective layer 9, and the third protective layer 100 need to be staggered at the boundary of the first frame region B1. Other peripheral regions (such as the upper frame region, the left frame region, and the right frame region) except the first frame region B1 do not need to be provided with the metal lapping holes V. Therefore, the first protective layer 8, the second protective layer 9 or the third protective layer 100 do not need to be staggered in the upper frame region, the left frame region and the right frame region, and are set with flush orthographic boundary.

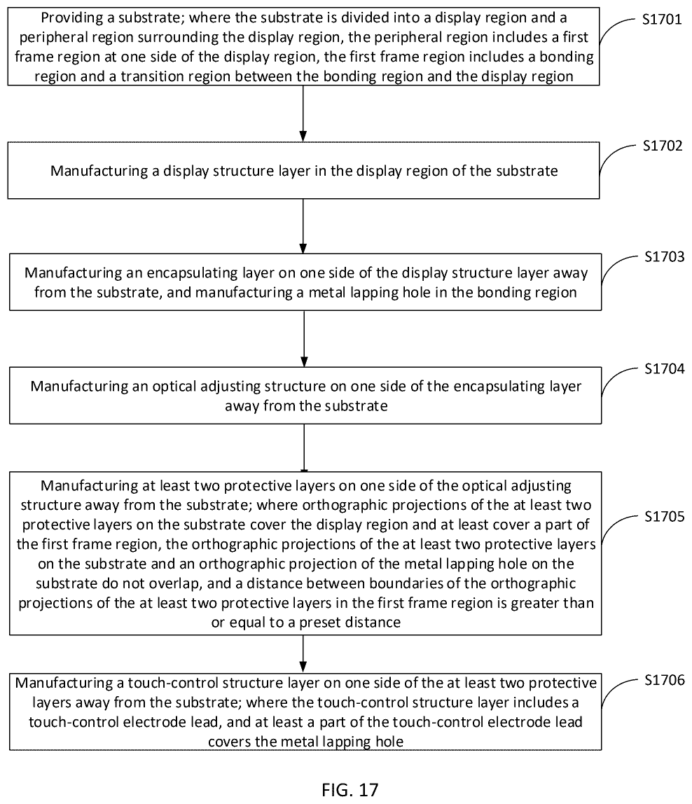

Based on the same inventive concept, an embodiment of the present disclosure further provides a manufacturing method for a touch-control display panel, as shown in FIG. 17, including following steps.
S1701: Providing a substrate; where the substrate is divided into a display region and a peripheral region surrounding the display region, the peripheral region includes a first frame region at one side of the display region, the first frame region includes a bonding region and a transition region between the bonding region and the display region.
S1702: Manufacturing a display structure layer in the display region of the substrate.
S1703: Manufacturing an encapsulating layer on one side of the display structure layer away from the substrate, and manufacturing a metal lapping hole in the bonding region.
S1704: Manufacturing an optical adjusting structure on one side of the encapsulating layer away from the substrate.
S1705: Manufacturing at least two protective layers on one side of the optical adjusting structure away from the substrate; where orthographic projections of the at least two protective layers on the substrate cover the display region and at least cover a part of the first frame region, the orthographic projections of the at least two protective layers on the substrate and an orthographic projection of the metal lapping hole on the substrate do not overlap, and a distance between boundaries of the orthographic projections of the at least two protective layers in the first frame region is greater than or equal to a preset distance.
S1706: Manufacturing a touch-control structure layer on one side of the at least two protective layers away from the substrate; where the touch-control structure layer includes a touch-control electrode lead, and at least a part of the touch-control electrode lead covers the metal lapping hole.

According to the manufacturing method for the touch-control display panel according to an embodiment of the present disclosure, by setting the distance between the boundaries of the orthographic projections of the at least two protective layer in the first frame region to be greater than or equal to the preset distance, it can be avoided that the distance between the boundaries of the orthographic projections of the at least two protective layers in the first frame region is too close to cause the problem that the height of the boundary position is too high. When a photoresist process is adopted to manufacture the touch control electrode lead, no metal residue is generated in the metal lapping hole, to ensure the touch-control performance.

It should be noted that, in the manufacturing method for the touch-control display panel according to an embodiment of the present disclosure, the manufacturing process used for each layer is the same as that in the related art. The difference is that the manufacturing sequence of each film layer in the touch-control display panel according to an embodiment of the present disclosure is different from that in the related art. When manufacturing the first protective layer, the second protective layer and the third protective layer, it is necessary to stagger the first boundary, the second boundary and the third boundary respectively in the first frame region, so that the distance between two adjacent boundaries is greater than the preset distance.

Based on the same inventive concept, an embodiment of the present disclosure further provides a display device including the touch-control display panel according to embodiments of the present disclosure. The principle of the display device for solving the problem is similar to that of the touch-control display panel. Therefore, the implementation of the display device can be referred to the implementation of the touch-control display panel, and the repetition is not repeated here.

In practice, the display device according to an embodiment of the present disclosure may be an organic light emitting display device or a liquid crystal display device, which is not limited herein.

In a specific implementation, the display device according to an embodiment of the present disclosure may be a full screen display device, or may be a flexible display device or the like, which is not limited herein.

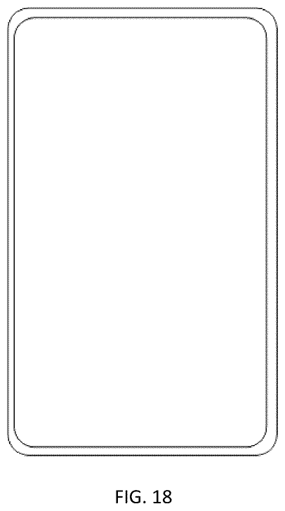

In a specific implementation, the display device according to an embodiment of the present disclosure may be a mobile phone with a full screen as shown in FIG. 18. Of course, The display device according to an embodiment of the present disclosure may also be any product or component with display function, such as a tablet computer, a television, a display, a notebook computer, a digital photo frame, navigation device. Other essential components of the display device are as will be understood by those skilled in the art, and are not intended to be exhaustive or to be limiting of the present disclosure.

Embodiments of the present disclosure provide a touch-control display panel, a manufacturing method therefor, and a display device. By adopting the encapsulating layer with a single film layer design, and the optical adjusting structure is firstly manufactured after the encapsulating layer and then the touch-control structure layer is manufactured, the encapsulating layer can not only encapsulate the display structure layer, but also improve the water and oxygen resistance of the display panel. Moreover, only one encapsulating layer is arranged between the display structure layer and the optical adjusting structure. Compared with the related art, the distance between the display structure layer and the optical adjusting structure is reduced. On the one hand, the film thickness of the display panel is reduced, and on the other hand, the L-Decay angle is improved. According to the present disclosure, the second protective layer is arranged between the first protective layer and the touch-control structure layer, so that the touch-control performance can be ensured. According to the present disclosure, the distance between the boundaries of the orthographic projections of at least two protective layers in the first frame region is set to be greater than or equal to the preset distance. In this way, it can be avoided that the distance between the boundaries of the orthographic projections of the at least two protective layers in the first frame region is too close to cause the problem that heights of the at least two protective layers at boundary positions are too high. When a photoresist process is adopted to manufacture the touch-control electrode lead, no metal residue is generated in the metal lapping hole, to ensure the touch-control performance.

Apparently, those skilled in the art can make various modifications and variations to embodiments of the present disclosure without departing from the spirit and scope of embodiments of the present disclosure. In this way, if the modifications and variations of embodiments of the present disclosure fall within the scope of the claims of the present disclosure and their equivalent technologies, the present disclosure is also intended to include these modifications and variations.

1.-20. (canceled)

21. A touch-control display panel, comprising a display region and a peripheral region surrounding the display region; wherein the peripheral region comprises a first frame region at one side of the display region, the first frame region comprises a bonding region and a transition region between the bonding region and the display region; the touch-control display panel comprises:
a substrate;
a display structure layer, arranged on the substrate and located in the display region;
an encapsulating layer, on one side of the display structure layer away from the substrate, wherein at least a part of the encapsulating layer is located in the display region;
an optical adjusting structure, on one side of the encapsulating layer away from the substrate;
a metal lapping hole, disposed on the substrate and located in the bonding region;
at least two protective layers, on one side of the optical adjusting structure away from the substrate, wherein orthographic projections of the at least two protective layers on the substrate cover the display region and at least cover a part of the first frame region, the orthographic projections of the at least two protective layers on the substrate and an orthographic projection of the metal lapping hole on the substrate do not overlap, and a distance between boundaries of the orthographic projections of the at least two protective layers in the first frame region is greater than or equal to a preset distance; and
a touch-control structure layer, on one side of the at least two protective layers away from the substrate, wherein the touch-control structure layer comprises a touch-control electrode lead, and at least a part of the touch-control electrode lead covers the metal lapping hole.

22. The touch-control display panel according to claim 21, further comprising a first blocking dam and a second blocking dam in the transition region and spaced apart, wherein the first blocking dam surrounds a periphery of the display region, the second blocking dam surrounds a periphery of the first blocking dam;
wherein the at least two protective layers comprise a first protective layer, a boundary of an orthographic projection of the first protective layer on the substrate comprises a first boundary in the first frame region, and the first boundary is on one side of the second blocking dam away from the first blocking dam.

23. The touch-control display panel according to claim 22, wherein the bonding region comprises a first metal lapping electrode on the substrate, the first frame region comprises a first planarization structure on one side of the first metal lapping electrode away from the substrate, an orthographic projection of the first planarization structure on the substrate covers the bonding region and a part of the transition region, and the first planarization structure and the second blocking dam are spaced apart, the first planarization structure comprises the metal lapping hole, and an orthographic projection of the metal lapping hole on the substrate is within a range of an orthographic projection of the first metal lapping electrode on the substrate;
the first boundary is at least within an edge of the orthographic projection of the first planarization structure on the substrate.

24. The touch-control display panel according to claim 23, wherein the at least two protective layers further comprise a second protective layer; a boundary of an orthographic projection of the second protective layer on the substrate comprises a second boundary in the first frame region, the second boundary is on one side of the second blocking dam close to the display region, or, the second boundary is on one side of the first blocking dam close to the display region.

25. The touch-control display panel according to claim 23, wherein the first boundary is at least close to the metal lapping hole.

26. The touch-control display panel according to claim 23, wherein the first boundary is on one side of the metal lapping hole away from the display region, and the first protective layer comprises a first via hole, an orthographic projection of the first via hole on the substrate covers the orthographic projection of the metal lapping hole on the substrate.

27. The touch-control display panel according to claim 25, wherein the at least two protective layers further comprise a second protective layer; a boundary of an orthographic projection of the second protective layer on the substrate comprises a second boundary in the first frame region, the second boundary is between the first planarization structure and the display region.

28. The touch-control display panel according to claim 26, wherein a thickness of the first protective layer in a region of the metal lapping hole is less than 3 μm.

29. The touch-control display panel according to claim 22, wherein the first protective layer is between the optical adjusting structure and the touch-control structure layer, and a second protective layer is between the first protective layer and the optical adjusting structure.

30. The touch-control display panel according to claim 22, wherein the first protective layer is between the optical adjusting structure and the touch-control structure layer, and a second protective layer is between the first protective layer and the touch-control structure layer.

31. The touch-control display panel according to claim 30, wherein a thickness of the first protective layer and a thickness of the second protective layer are both less than 2 μm.

32. The touch-control display panel according to claim 24, wherein the display panel further comprises a third protective layer between the second protective layer and the touch-control structure layer, a boundary of an orthographic projection of the third protective layer on the substrate comprises a third boundary in the transition region, the third boundary is between the second boundary and the display region, and a distance between the third boundary and the second boundary is greater than or equal to the preset distance.

33. The touch-control display panel according to claim 32, wherein along a direction of the substrate pointing to the touch-control structure layer, a thickness of the first protective layer is greater than a thickness of the second protective layer, and the thickness of the second protective layer is greater than a thickness of the third protective layer.

34. The touch-control display panel according to claim 21, wherein the at least two protective layers are organic material layers.

35. The touch-control display panel according to claim 21, wherein the preset distance is greater than or equal to 50 μm.

36. The touch-control display panel according to claim 21, wherein the display structure layer comprises a driving array layer between the substrate and the encapsulating layer, and a light emitting structure layer between the driving array layer and the encapsulating layer;
the driving array layer comprises a first source-drain metal layer and a second source-drain metal layer stacked, the first metal lapping electrode and the second source-drain metal layer are on the same layer.

37. The touch-control display panel according to claim 36, wherein the bonding region further comprises a second metal lapping electrode between the substrate and the first metal lapping electrode and insulated from the substrate and the first metal lapping electrode, the second metal lapping electrode and the first source-drain metal layer are on the same layer, the first metal lapping electrode and the second metal lapping electrode are connected through a via hole.

38. The touch-control display panel according to claim 36, wherein the optical adjusting structure comprises a color film layer and a black matrix layer; the color film layer comprises a plurality of color films of different colors on the same layer and sequentially and circularly arranged, the black matrix layer has a plurality of openings, the color films are in the openings;
orthographic projections of adjacent color films on the substrate are overlapped or not overlapped;
the color films correspond to light emitting regions in the light emitting structure layer, the color films are used for transmitting light emitted from the light emitting regions through corresponding color films.

39. A display device, comprising the touch-control display panel according to claim 21.

40. A manufacturing method for a touch-control display panel, comprising:
providing a substrate, wherein the substrate is divided into a display region and a peripheral region surrounding the display region, the peripheral region comprises a first frame region at one side of the display region, the first frame region comprises a bonding region and a transition region between the bonding region and the display region;
manufacturing a display structure layer in the display region of the substrate;
manufacturing an encapsulating layer on one side of the display structure layer away from the substrate, and manufacturing a metal lapping hole in the bonding region;
manufacturing an optical adjusting structure on one side of the encapsulating layer away from the substrate;
manufacturing at least two protective layers on one side of the optical adjusting structure away from the substrate, wherein orthographic projections of the at least two protective layers on the substrate cover the display region and at least cover a part of the first frame region, the orthographic projection of the at least two protective layers on the substrate and an orthographic projection of the metal lapping hole on the substrate do not overlap, and a distance between boundaries of the orthographic projections of the at least two protective layers in the first frame region is greater than or equal to a preset distance; and
manufacturing a touch-control structure layer on one side of the at least two protective layers away from the substrate; wherein the touch-control structure layer comprises a touch-control electrode lead, and at least a part of the touch-control electrode lead covers the metal lapping hole.
